(19) United States
(12) Patent Application Publication
(10) Pub. No.: US 2025/0014864 A1
(43) Pub. Date: Jan. 9, 2025

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 18/755,946

(22) Filed: Jun. 27, 2024

(30) Foreign Application Priority Data
Jul. 7, 2023 (JP) 2023-112413

(51) Int. Cl. H01J 37/32

(52) U.S. Cl. CPC H01J 37/321; H01J 2237/327

(57) ABSTRACT

A plasma processing apparatus includes a chamber, a substrate support, an excitation electrode, and a resonator. The resonator includes an inner side portion and an outer side portion extending coaxially, and conductive plates arranged parallel to each other in a vertical direction. The resonator provides a waveguide path extending between the inner and outer side portions and including a plurality of layers arranged alternately with the conductive plates. Each of the plurality of layers is connected to a layer thereabove at one of a plurality of folded portions along the inner side portion or the outer side portion. A lowermost conductive plate includes a plurality of slots electromagnetically coupled to the discharger. The plurality of slots is arranged in a circumferential direction, and a wall surrounding a lowermost layer in the outer side portion extends along sides of a polygon.

### CROSS-REFERENCE TO RELATED APPLICATION

This application is based upon and claims the benefit of priority from Japanese Patent Application No. 2023-112413, filed on Jul. 7, 2023, the entire contents of which are incorporated herein by reference.

### TECHNICAL FIELD

Exemplary embodiments of the present disclosure relate to a plasma processing apparatus.

### BACKGROUND

A plasma processing apparatus is used in processing a substrate. As a type of plasma processing apparatus, an apparatus that excites gas using radio frequency waves such as very radio frequency (VHF) waves or ultra radio frequency (UHF) waves is known. Patent Document 1 below discloses such a plasma processing apparatus. The plasma processing apparatus of Patent Document 1 includes a processing container, a stage, an upper electrode, an introducer, and a waveguide portion. The stage is provided in the processing container. The upper electrode is provided above the stage with a space in the processing container interposed therebetween. The introducer is a radio frequency introducer. The introducer is provided at an end of the space in a lateral direction and extends in a circumferential direction around a central axis line of the processing container. The waveguide portion is configured to supply radio frequency waves to the introducer. The waveguide portion includes a resonator that provides a waveguide path. The waveguide path of the resonator extends circumferentially around the central axis line and extends in a direction in which the central axis line extends so as to be connected to the introducer.

### PRIOR ART DOCUMENT

### [Patent Document]

Patent Document 1: Japanese Patent Laid-Open Publication No. 2020-92031

### SUMMARY

According to one embodiment of the present disclosure, a plasma processing apparatus includes a chamber configured to provide a processing space therein; a substrate support provided in the processing space; an excitation electrode provided above the substrate support; a discharger provided to discharge electromagnetic waves into a plasma generation space below the excitation electrode; and a resonator provided on the excitation electrode and electromagnetically coupled to the discharger. The discharger extends around a central axis line of the chamber and the excitation electrode. The resonator includes an inner side portion and an outer side portion extending coaxially with respect to the central axis line, and a plurality of conductive plates arranged parallel to each other in a vertical direction, which is a direction in which the central axis line extends. The resonator provides a waveguide path extending between the outer side portion and the inner side portion and including a plurality of layers arranged alternately with the plurality of conductive plates. Each of the plurality of layers is connected to a layer thereabove among the plurality of layers at one of a plurality of folded portions along the inner side portion or the outer side portion. A lowermost conductive plate among the plurality of conductive plates includes a plurality of slots electromagnetically coupled to the discharger. The plurality of slots is arranged in a circumferential direction with respect to the central axis line, and a wall surrounding a lowermost layer among the plurality of layers in the outer side portion extends along sides of a polygon in cross section perpendicular to the central axis line.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is a cross-sectional view taken along line II-II in FIG. 1.

FIG. 3 is a diagram illustrating a plasma processing apparatus according to another exemplary embodiment.

FIG. 4 is a cross-sectional view taken along line IV-IV in FIG. 3.

FIG. 5 is a cross-sectional view taken along line V-V in FIG. 3.

FIG. 6 is a cross-sectional view taken along line VI-VI in FIG. 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In each drawing, the same or corresponding components are denoted by the same reference numerals.

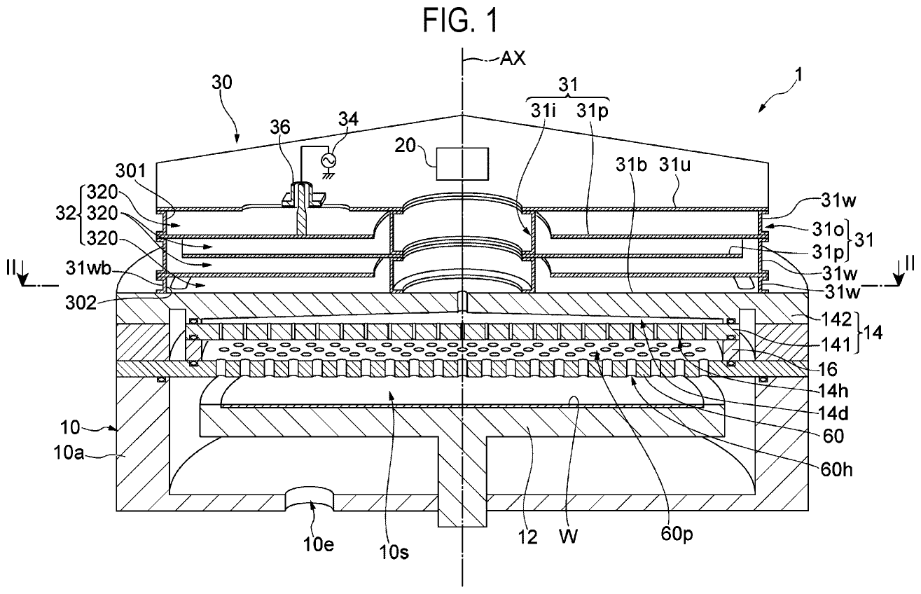

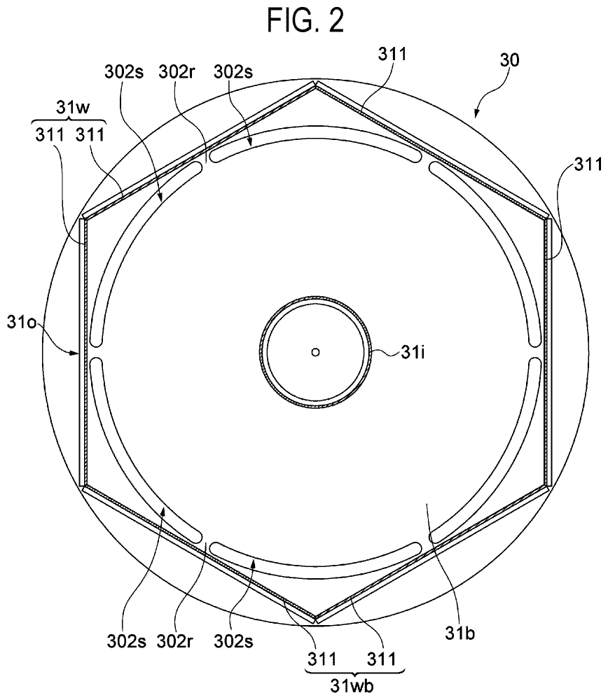

FIG. 1 is a diagram illustrating a plasma processing apparatus according to one exemplary embodiment. FIG. 2 is a cross-sectional view taken along line II-II in FIG. 1. A plasma processing apparatus 1 illustrated in FIGS. 1 and 2 includes a chamber 10, a substrate support 12, an excitation electrode 14, a discharger 16, and a resonator 30.

The chamber 10 includes a processing space 10s in the chamber 10. In the plasma processing apparatus 1, a substrate W is processed inside the processing space 10s. The chamber 10 is made of a metal such as aluminum and is grounded. The chamber 10 has a side wall 10a and is open at its upper end. The chamber 10 and the side wall 10a may have a substantially cylindrical shape. The processing space 10s is provided inside the side wall 10a. A central axis line of each of the chamber 10, the side wall 10a, and the processing space 10s is an axis line AX. The chamber 10 may have a corrosion-resistant film on the surface of the chamber 10. The corrosion-resistant film may be an yttrium oxide film, an yttrium oxide fluoride film, an yttrium fluoride film, or a ceramic film including yttrium oxide, yttrium fluoride, or the like.

An exhaust port 10e is formed in a bottom of the chamber 10. An exhaust device is connected to the exhaust port 10e. The exhaust device may include a vacuum pump, such as a dry pump and/or a turbomolecular pump, and an automatic pressure control valve.

The substrate support 12 is installed in the processing space 10s. The substrate support 12 is configured to substantially horizontally support the substrate W on an upper surface of the substrate support 12. The substrate support 12 has a substantially disc shape. A central axis line of the substrate support 12 is the axis line AX.

The excitation electrode 14 is installed above the substrate support 12 with the processing space 10s interposed therebetween. The excitation electrode 14 is made of a conductive material such as a metal (e.g., aluminum) and has a substantially disc shape. A central axis line of the excitation electrode 14 is the axis line AX.

The plasma processing apparatus 1 further includes an electrode 60. The electrode 60 is another excitation electrode. The electrode 60 has a substantially disc shape and is disposed so as to close an opening of the upper end of the chamber 10. The electrode 60 provides a plurality of holes 60h. The plurality of holes 60h penetrates the electrode 60 in a thickness direction. The excitation electrode 14 is disposed above the electrode 60. The excitation electrode 14 and the electrode 60 form a plasma generation space 60p therebetween. In the plasma processing apparatus 1, the plasma generation space 60p is separated from the processing space 10s and is provided above the processing space 10s.

The discharger 16 is provided to discharge electromagnetic waves therefrom into the plasma generation space 60p. In the plasma processing apparatus 1, the discharger 16 surrounds the plasma generation space 60p and is supported between the excitation electrode 14 and the electrode 60. The electromagnetic waves discharged from the discharger 16 into the plasma generation space 60p may be radio frequency waves such as VHF waves or UHF waves. The discharger 16 is formed of a dielectric material such as quartz, aluminum nitride, or aluminum oxide. The discharger 16 extends in a circumferential direction around the axis line AX. The discharger 16 may have an annular shape.

In one embodiment, the excitation electrode 14 may include a shower plate 141 and an upper electrode 142. The shower plate 141 is provided above the plasma generation space 60p. The shower plate 141 provides a plurality of gas holes h. The plurality of gas holes 14h extends in a thickness direction (vertical direction) of the shower plate 141 and penetrates the shower plate 141.

The upper electrode 142 is provided on the shower plate 141. The upper electrode 142 forms a gas diffusion chamber 14d between the shower plate 141 and the upper electrode 142. A gas supply 20 is connected to the gas diffusion chamber 14d. Gas from the gas supply 20 is discharged into the plasma generation space 60p from the plurality of gas holes 14h via the gas diffusion chamber 14d.

In the plasma processing apparatus 1, the gas in the plasma generation space 60p is excited by the electromagnetic waves discharged from the discharger 16 into the plasma generation space 60p. As a result, plasma is generated in the plasma generation space 60p. Active species in the plasma generated in the plasma generation space 60p are supplied to the processing space 10s from the plurality of holes 60h.

The resonator 30 is installed on the excitation electrode 14. The resonator 30 is electromagnetically coupled to the discharger 16. The resonator 30 includes a waveguide path 32. The resonator 30 includes a conductive portion 31 that defines the waveguide path 32. The conductive portion 31 is made of a conductive material such as a metal. The conductive material forming the conductive portion 31 may include aluminum, stainless steel, copper, or brass.

The resonator 30 includes a first end 301 and a second end 302. The first end 301 is one end of the waveguide path 32, and the second end 302 is the other end of the waveguide path 32. The resonator 30 is configured to reflect electromagnetic waves propagating within the waveguide path 32 at the first end 301 and the second end 302 and cause the electromagnetic waves to resonate. The electromagnetic waves resonating in the resonator 30 are supplied to the discharger 16 from a plurality of slots 302s, which will be described later, and are discharged into the plasma generation space.

The plasma processing apparatus 1 may further include a radio frequency power supply 34. The radio frequency power supply 34 is configured to generate radio frequency power. The electromagnetic waves introduced into the plasma generation space is generated based on the radio frequency power generated by the radio frequency power supply 34. The radio frequency power supply 34 may be directly connected to the resonator 30 using a coaxial line. That is, the radio frequency power supply 34 may be coupled to the waveguide path of the resonator 30 without using a matcher for impedance matching. The coaxial line may include a connector 36 as a connection portion to the resonator 30. The connector 36 may be connected to the resonator 30 so as to introduce the electromagnetic waves into the resonator 30 from the uppermost layer of a plurality of layers 320, which will be described later, of the waveguide path 32. In this case, an inner conductor of the connector 36 is connected to a conductive plate 31p, which will be described later, that defines the uppermost layer from below, and an outer conductor of the connector 36 is connected to a conductive plate 31p (upper wall 31u) that defines the uppermost layer from above.

In one embodiment, the waveguide path 32 may have a folded structure including a plurality of folded portions. In one embodiment, the waveguide path 32 may be configured axially or rotationally symmetrically with respect to the axis line AX. Further, in one embodiment, the conductive portion 31 may include an inner side portion 31i (or an inner peripheral portion), an outer side portion 31o (or an outer peripheral portion), and a plurality of conductive plates 31p. The inner side portion 31i and the outer side portion 31o extend coaxially with respect to the axis line AX. The plurality of conductive plates 31p extends radially with respect to the axis line AX and is arranged parallel to each other in the vertical direction, which is a direction in which the axis line AX extends.

Additionally, the waveguide path 32 may include the plurality of layers 320. The plurality of layers 320 extends in a radial direction with respect to the axis line AX between the inner side portion 31i and the outer side portion 31o and is arranged alternately with the plurality of conductive plates 31p. Each of the plurality of layers 320 is connected to a layer thereabove among the plurality of layers 320 at one of the plurality of folded portions along the inner side portion 31i or the outer side portion 31o.

In one embodiment, the first end 301 is provided above the second end 302. The first end 301 is provided by the outer side portion 31o of the resonator 30. The first end 301 surrounds the uppermost layer of the plurality of layers 320. The second end 302 is composed of a wall 31wb of the outer side portion 31o surrounding the lowermost layer among the plurality of layers 320. The second end 302 extends in the circumferential direction around the axis line AX above the discharger 16. As illustrated in FIG. 2, the plurality of slots 302s is formed in a lowest conductive plate 31b that defines the lowermost layer from below among the plurality of conductive plates 31p. In the plasma processing apparatus 1, the conductive plate 31b also serves as the upper electrode 142. The plurality of slots 302s is disposed near the second end 302 or along the second end 302. The plurality of slots 302s is coupled to the discharger 16 externally to the excitation electrode 14. The plurality of slots 302s extends in a circumferential direction with respect to the axis line AX and is arranged in the circumferential direction. In one embodiment, a radial distance between the axis line AX and an outer edge of each of the plurality of slots 302s may be substantially identical to the radius of an inscribed circle of a polygon of the wall 31wb. In this resonator 30, the electromagnetic waves are reflected toward the first end 301 at the second end 302. Further, some of the electromagnetic waves propagating in the resonator 30 are coupled to the discharger 16 through the plurality of slots 302s.

In the plasma processing apparatus 1, the inner side portion 31i may have a substantially cylindrical shape having a central axis of the axis line AX. The inner side portion 31i may be formed of a tubular (e.g., cylindrical) conductive wall extending between the conductive plates 31p which are adjacent in the vertical direction.

In the plasma processing apparatus 1, the outer side portion 31o has a substantially tubular shape and has the axis line AX as a central axis thereof. The outer side portion 31o may include a plurality of walls 31w including the wall 31wb surrounding the lowermost layer and walls surrounding upper layers other than the lowermost layer among the plurality of layers 320. Each of the plurality of walls 31w extends between the corresponding conductive plates 31p adjacent to each other in the vertical direction and has a substantially tubular shape. The wall 31wb surrounding at least the lowermost layer of the plurality of walls 31w extends along sides of a polygon in cross section perpendicular to the axis line AX. Two or more or all of the walls 31w among the plurality of walls 31w may extend along the sides of the polygon in cross section perpendicular to the axis line AX. In one embodiment, the wall 31wb may have a polygonal tube shape. Further, each of two or more or all of the walls 31w among the plurality of walls 31w may each have a polygonal tube shape. In addition, in the example illustrated in FIG. 1 and FIG. 2, the polygon is a regular hexagon, but other polygons may be used as the polygon.

In one embodiment, the wall 31wb may be formed of a plurality of plate-like bodies 311. Further, each of two or more of the plurality of walls 31w or each of all of the walls 31w may be formed of the plurality of plate-like bodies 311. Each of the plurality of plate-like bodies 311 is formed of the above-mentioned metal. Each of the plurality of plate-like bodies 311 may be a flat plate. Each of the plurality of plate-like bodies 311 extends along a corresponding side of the polygon in a cross-section perpendicular to the axis line AX.

In the resonator 30, the magnitude of a current flowing into the conductive plate 31b in the radial direction with respect to the axis line AX has a distribution in a circumferential direction, in which the magnitude of the current is minimum in a direction from the axis line AX toward each corner of the polygon and is maximum at the center of each side of the polygon. Therefore, in each of the plurality of slots 302s, a distribution of electric field intensity is adjusted in the circumferential direction.

In one embodiment, the number of the plurality of slots 302s and the number of a plurality of corners of the polygon may be equal. Moreover, the position of each of the plurality of corners of the polygon and a center position of a corresponding slot in the circumferential direction among the plurality of slots 302s may be aligned in the radial direction with respect to the axis line AX. Normally, the magnitude of displacement current flowing in the radial direction toward the center of each of the slot 302s in the conductive plate 31b is the maximum. However, in the resonator 30, the magnitude of current flowing into the conductive plate 31b in the radial direction has a distribution in the circumferential direction, in which the magnitude of current is weakened at the center of each of the plurality of slots 302s and is strengthened between the adjacent slots 302s. Therefore, in each of the plurality of slots 302s, uniformity of a distribution of electric field intensity in the circumferential direction is increased.

As illustrated in FIGS. 1 and 2, an edge of each of the plurality of plate-like bodies 311 extending in the vertical direction is connected to an edge of another corresponding plate-like body extending in the vertical direction among the plurality of plate-like bodies 311 at a corresponding corner of the polygon. However, the plurality of plate-like bodies 311 may be spaced apart from each other so as to provide gaps at the corners of the polygon. When the plurality of plate-like bodies 311 is spaced apart from each other so as to provide the gaps at the corners of the polygon, the magnitude of current flowing toward the corners of the polygon in the radial direction is further reduced.

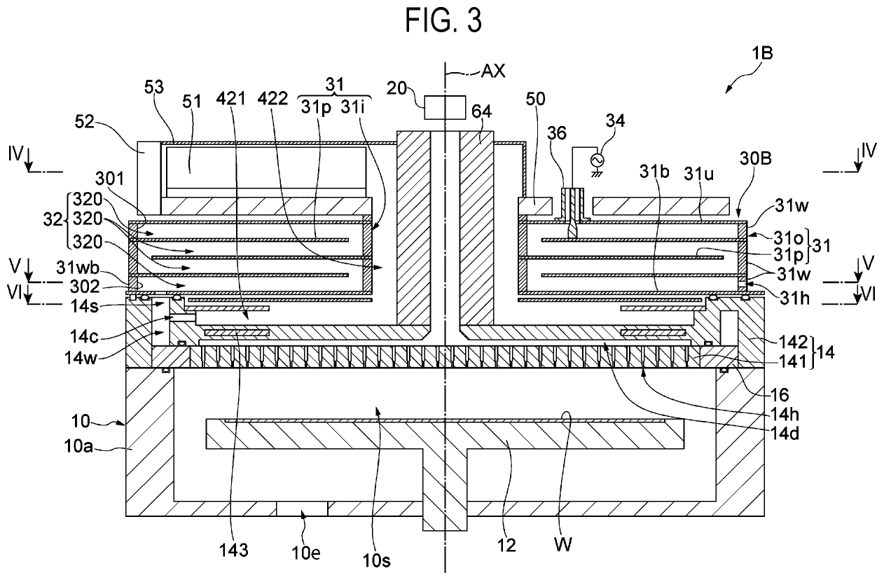

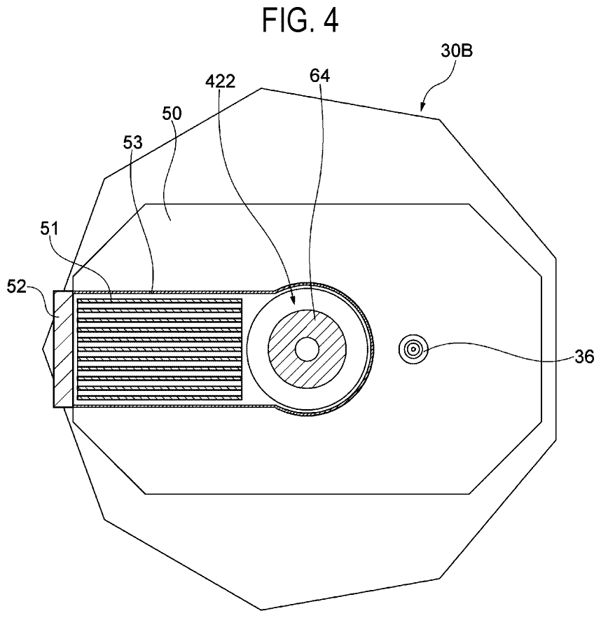

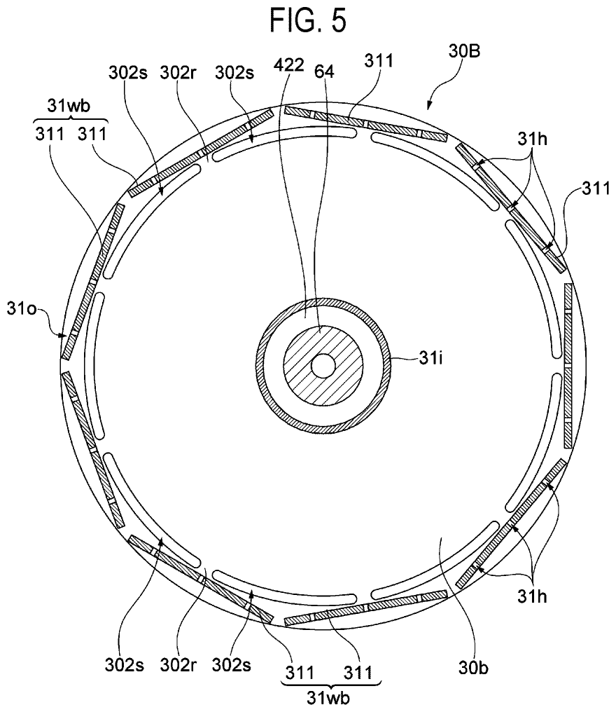

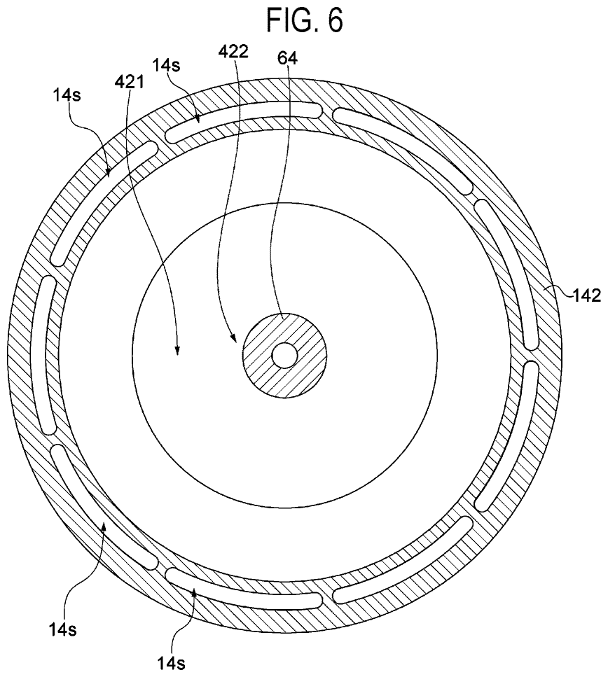

Hereinafter, a plasma processing apparatus according to another exemplary embodiment will be described with reference to FIGS. 3 to 6. FIG. 3 is a diagram illustrating a plasma processing apparatus according to another exemplary embodiment. FIG. 4 is a cross-sectional view taken along line IV-IV in FIG. 3. FIG. 5 is a cross-sectional view taken along line V-V in FIG. 3. FIG. 6 is a cross-sectional view taken along line VI-VI in FIG. 3. Hereinafter, a plasma processing apparatus 1B illustrated in FIGS. 3 to 6 will be described from the viewpoint of differences from the plasma processing apparatus 1.

The plasma processing apparatus 1B does not include the electrode 60. In the plasma processing apparatus 1B, the discharger 16 extends to surround the shower plate 141. The shower plate 141 and the discharger 16 close the opening of the upper end of the chamber 10. In the plasma processing apparatus 1B, the plasma generation space is a space which is within the processing space 10s and is directly below the shower plate 141.

The plasma processing apparatus 1B may further include a gas pipe 64. The gas pipe 64 extends inside the inner side portion 31i in the vertical direction. A central axis line of the gas pipe 64 is located on the axis line AX. The gas pipe 64 is connected between the gas diffusion chamber 14d and the gas supply 20.

The plasma processing apparatus 1B includes a resonator 30B instead of the resonator 30. Hereinafter, the resonator 30B will be described from the viewpoint of differences from the resonator 30. In the resonator 30B, the plurality of slots 302s is formed in the conductive plate 31b different from the upper electrode 142. The conductive plate 31b extends above the upper electrode 142.

In the resonator 30B, the number of the slots 302s is nine. That is, the number of the slots 302s is an odd number. When the number of the slots 302s is an odd number, generation of an electric field intensity distribution (or plasma density distribution), which has a two-fold rotational symmetry around the axis line AX in the plasma generation space, is suppressed as compared to the case in which the number of the slots 302s is an even number. If the number of the slots 302s is five or more, the number of the slots 302s may be an odd number other than nine. Further, the number of slots 302s in the resonator 30B may be an even number.

Even in the plasma processing apparatus 1B, similarly to the plasma processing apparatus 1, the wall 31wb of the outer side portion 31o extends along the sides of the polygon in cross section perpendicular to the axis line AX. Two or more or all of the walls 31w among the plurality of walls 31w may extend along the sides of the polygon in cross section perpendicular to the axis line AX. In the plasma processing apparatus 1B, the plurality of plate-like bodies 311 is spaced apart from each other so as to provide gaps at the corners of the polygon. However, even in the plasma processing apparatus 1B, an edge of each of the plurality of plate-like bodies 311 vertically extending may be connected to an edge of another corresponding plate-like body vertically extending among the plurality of plate-like bodies 311 at a corresponding corner of the polygon.

Even in the plasma processing apparatus 1B, similarly to the plasma processing apparatus 1, the number of the plurality of slots 302s and the number of the plurality of corners of the polygon may be equal. Therefore, in the plasma processing apparatus 1B, the number of corners of the polygon may be an odd number. In the illustrated example, the polygon is a regular nonagon. Even in the plasma processing apparatus 1B, the position of each of the plurality of corners of the polygon and the center position of a corresponding slot in the circumferential direction among the plurality of slots 302s may be aligned in the radial direction with respect to the axis line AX.

Further, the resonator 30B provides a plurality of inlets 31h, which connects the and the outside of the resonator 30B to each other, in any wall 31w of the outer side portion 31o. The plurality of inlets 31h may be arranged in the circumferential direction. In one embodiment, the plurality of inlets 31h is provided in the wall 31wb and connects the lowermost layer of the plurality of layers 320 of the waveguide path 32 to the outside of the resonator 30B.

In the plasma processing apparatus 1B, the excitation electrode 14 (e.g., the upper electrode 142) may have a heating mechanism 143 built therein. The heating mechanism 143 may be a heater, such as a resistive heating element. In this case, the heating mechanism 143 is connected to a heater power supply. The power of the heater power supply may be controlled by a controller depending on a difference between a temperature value of the excitation electrode 14 measured by a temperature sensor and a target temperature value of the excitation electrode 14.

In the plasma processing apparatus 1B, the upper electrode 142 provides a plurality of slots 14s. The plurality of slots 14s is provided directly below the plurality of slots 302s, respectively. The upper electrode 142 provides a waveguide path 14w between each of the plurality of slots 302s and the discharger 16. The waveguide path 14w extends in the circumferential direction centered on the axis line AX and has an annular shape when viewed in a plan view. In the plasma processing apparatus 1B, electromagnetic waves discharged from the plurality of slots 302s are supplied to the discharger 16 via the plurality of slots 14s and the waveguide path 14w.

Further, the upper electrode 142 provides a cavity 421 which is positioned radially inside the waveguide path 14w and between the upper electrode 142 and the resonator 30B. The cavity 421 is connected to the waveguide path 14w via a plurality of communication holes 14c. The plurality of communication holes 14c is arranged in the circumferential direction. In the plasma processing apparatus 1B, the cavity 421 is connected to a space outside the resonator 30B via the inlet 31h, the waveguide path 32, the plurality of slots 302s, the plurality of slots 14s, the waveguide path 14w, and the plurality of communication holes 14c.

The plasma processing apparatus 1B further includes a heat sink 51 and a fan 52. The heat sink 51 is disposed on a support body 50 above the resonator 30B. The fan 52 is supported by the support body 50 and is connected to a flow path in the heat sink 51. Further, in the plasma processing apparatus 1B, a cavity 422 is provided between the inner side portion 31i of the resonator 30B and the gas pipe 64. The cavity 422 is connected between the cavity 421 and the flow path of the heat sink 51. The cavity 421 and the heat sink 51 are covered by a cover 53.

In the plasma processing apparatus 1B, gas (e.g., atmospheric air) outside the resonator 30B is supplied to the cavity 421 via the inlet 31h, the waveguide path 32, the plurality of slots 302s, the plurality of slots 14s, the waveguide path 14w, and the plurality of communication holes 14c. The gas supplied to the cavity 421 flows along the upper surface of the upper electrode 142 and exchanges heat with the upper electrode 142, i.e., the excitation electrode 14. Thereafter, the gas is supplied to the flow path in the heat sink 51 via the cavity 422, cooled in the heat sink 51, and discharged to the outside from the fan 52.

While various embodiments have been described, these embodiments are not intended to limit the scope of the disclosure. Various omissions, substitutions and changes in the form of the embodiments described herein may be made. Another embodiment may be possible by combining the elements in different embodiments.

Herein, various exemplary embodiments included in the present disclosure are described in E1 to E8 below.

[E1] A plasma processing apparatus includes:
a chamber configured to provide a processing space therein;
a substrate support provided in the processing space;
an excitation electrode provided above the substrate support;
a discharger provided to discharge electromagnetic waves into a plasma generation space below the excitation electrode, and
a resonator provided on the excitation electrode and electromagnetically coupled to the discharger,
wherein the discharger extends around a central axis line of the chamber and the excitation electrode,
wherein the resonator includes an inner side portion and an outer side portion extending coaxially with respect to the central axis line, and a plurality of conductive plates arranged parallel to each other in a vertical direction, which is a direction in which the central axis line extends, and provides a waveguide path extending between the outer side portion and the inner side portion and including a plurality of layers arranged alternately with the plurality of conductive plates,
wherein each of the plurality of layers is connected to a layer thereabove among the plurality of layers at one of a plurality of folded portions along the inner side portion or the outer side portion;
wherein a lowermost conductive plate among the plurality of conductive plates includes a plurality of slots electromagnetically coupled to the discharger,
wherein the plurality of slots is arranged in a circumferential direction with respect to the central axis line, and
wherein a wall surrounding a lowermost layer among the plurality of layers in the outer side portion extends along sides of a polygon in cross section perpendicular to the central axis line.

[E2] In the plasma processing apparatus of E1, the number of the plurality of slots and the number of a plurality of corners of the polygon are equal.

[E3] In the plasma processing apparatus of E2, a position of each of the plurality of corners of the polygon and a center position of a corresponding slot in the circumferential direction among the plurality of slots are aligned in a radial direction with respect to the central axis line.

[E4] In the plasma processing apparatus of any one of E1 to E3, a radial distance between the central axis line and an outer edge of each of the plurality of slots is substantially identical to a radius of an inscribed circle of the polygon.

[E5] In the plasma processing apparatus of any one of E1 to E4, the wall surrounding the lowermost layer is composed of a plurality of plate-like bodies made of a metal, and the plurality of plate-like bodies constitutes a plurality of sides of the polygon, respectively.

[E6] In the plasma processing apparatus of E5, an edge of each of the plurality of plate-like bodies vertically extending is connected to an edge of another corresponding plate-like body vertically extending among the plurality of plate-like bodies at a corresponding corner of the polygon.

[E7] In the plasma processing apparatus of E5, the plurality of plate-like bodies is spaced apart from each other so as to provide gaps at corners of the polygon.

[E8] In the plasma processing apparatus of any one of E1 to E7, a wall surrounding each of the plurality of layers in the outer side portion extends along the sides of the polygon in cross section perpendicular to the central axis line.

According to one exemplary embodiment, it is possible to adjust an intensity distribution of an electric field in a slot of a resonator in a plasma processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a chamber configured to provide a processing space therein;
a substrate support provided in the processing space;
an excitation electrode provided above the substrate support;
a discharger provided to discharge electromagnetic waves into a plasma generation space below the excitation electrode; and
a resonator provided on the excitation electrode and electromagnetically coupled to the discharger,
wherein the discharger extends around a central axis line of the chamber and the excitation electrode,
wherein the resonator includes:
an inner side portion and an outer side portion extending coaxially with respect to the central axis line; and
a plurality of conductive plates arranged parallel to each other in a vertical direction, which is a direction in which the central axis line extends,
wherein the resonator provides a waveguide path extending between the outer side portion and the inner side portion and including a plurality of layers arranged alternately with the plurality of conductive plates,
wherein each of the plurality of layers is connected to a layer thereabove among the plurality of layers at one of a plurality of folded portions along the inner side portion or the outer side portion;
wherein a lowermost conductive plate among the plurality of conductive plates includes a plurality of slots electromagnetically coupled to the discharger,
wherein the plurality of slots is arranged in a circumferential direction with respect to the central axis line, and
wherein a wall surrounding a lowermost layer among the plurality of layers in the outer side portion extends along sides of a polygon in cross section perpendicular to the central axis line.

2. The plasma processing apparatus of claim 1, wherein a number of the plurality of slots and a number of a plurality of corners of the polygon are equal.

3. The plasma processing apparatus of claim 2, wherein a position of each of the plurality of corners of the polygon and a center position of a corresponding slot in the circumferential direction among the plurality of slots are aligned in a radial direction with respect to the central axis line.

4. The plasma processing apparatus of claim 3, wherein a radial distance between the central axis line and an outer edge of each of the plurality of slots is substantially identical to a radius of an inscribed circle of the polygon.

5. The plasma processing apparatus of claim 1, wherein a radial distance between the central axis line and an outer edge of each of the plurality of slots is substantially identical to a radius of an inscribed circle of the polygon.

6. The plasma processing apparatus of claim 1, wherein the wall surrounding the lowermost layer is composed of a plurality of plate-like bodies made of a metal, and wherein the plurality of plate-like bodies constitutes a plurality of sides of the polygon, respectively.

7. The plasma processing apparatus of claim 6, wherein an edge of each of the plurality of plate-like bodies vertically extending is connected to an edge of another corresponding plate-like body vertically extending among the plurality of plate-like bodies at a corresponding corner of the polygon.

8. The plasma processing apparatus of claim 6, wherein the plurality of plate-like bodies is spaced apart from each other so as to provide gaps at corners of the polygon.

9. The plasma processing apparatus of claim 1, wherein a wall surrounding each of the plurality of layers in the outer side portion extends along the sides of the polygon in cross section perpendicular to the central axis line.
